(19) United States
(12) Patent Application Publication
(10) Pub. No.: US 2026/0033045 A1
(43) Pub. Date: Jan. 29, 2026

(54) LIGHT-EMITTING DEVICE, DISPLAY APPARATUS AND BACKLIGHT APPARATUS

(71) Applicants: BOE MLED TECHNOLOGY CO., LTD., Beijing (CN); BOE TECHNOLOGY GROUP CO., LTD., Beijing (CN)

(72) Inventors: Yuanda LU, Beijing (CN); Yutian CHU, Beijing (CN); Zhijun XIONG, Beijing (CN); Jiawei ZHAO, Beijing (CN); Yuanhao SUN, Beijing (CN); Zedan CHEN, Beijing (CN); Qi FAN, Beijing (CN); Junjie MA, Beijing (CN)

(73) Assignees: BOE MLED TECHNOLOGY CO., LTD., Beijing (CN); BOE TECHNOLOGY GROUP CO., LTD., Beijing (CN)

(21) Appl. No.: 18/994,495

(22) PCT Filed: Mar. 31, 2023
(86) PCT No.: PCT/CN2023/085743

§ 371 Date: Jan. 14, 2025

(51) Int. Cl. H10H 20/831; H10H 20/813; H10H 20/833

(52) U.S. Cl. CPC H10H 20/8312; H10H 20/8132; H10H 20/833

(57) ABSTRACT

A light-emitting device, a display apparatus and a backlight apparatus are provided. The light-emitting device includes a sub-light-emitting unit. The sub-light-emitting unit includes: a first semiconductor layer; a second semiconductor layer, stacked with the first semiconductor layer and having a material different from a material of the first semiconductor layer; a light-emitting layer, located between the first semiconductor layer and the second semiconductor layer; a current spreading layer, located on a side of the first semiconductor layer away from the second semiconductor layer; and an insulating layer, located between the current spreading layer and the first semiconductor layer. The current spreading layer and the second semiconductor layer are electrically connected with the first semiconductor layer through a via hole penetrating the insulating layer.

### TECHNICAL FIELD

Embodiments of the present disclosure relate to a light-emitting device, a display apparatus and a backlight apparatus.

### BACKGROUND

LEDs (light emitting diodes) have the advantages of low cost, high light efficiency, energy saving and environmental protection, and are widely used in lighting, visible light communications, and luminous displays.

One of the development directions of the LEDs is towards miniaturization and miniaturization. LEDs are shrunk to form arrays with millimeter or even pitches in microns, which can achieve ultra-high resolution, and can be more widely used in information display and other fields.

At present, small-sized flip-chip LED chips have been widely used in backlight displays and RGB display apparatuses, and currently, display products on the market are installed upside down on a circuit substrate by using thousands or tens of thousands of flip-chip LED chips with a single light-emitting unit or flip-chip LED chips with two light-emitting units connected in series.

In a case that sizes of chips become smaller, distances between core particles become closer, and contrast of final display is higher, but the current used in chips becomes smaller, how to improve product performance becomes a development direction. Using high-voltage LEDs to replace existing normal-voltage LEDs can reduce current values of lines and increase a proportion of VLEDs while maintaining a same brightness, thereby reducing overall power consumption, and improving the competitiveness of Mini LED glass-based products. Compared with the manufacturing process of the normal-voltage LEDs, in the manufacturing process of the high-voltage LEDs, a single PN junction is divided into two PN junctions, and then the two PN junctions are connected through a bridge metal, thus the driving voltage is increased and the current used is reduced while the brightness of a single LED remains unchanged.

### SUMMARY

At least one embodiment of the disclosure provides a light-emitting device. The light-emitting device includes a sub-light-emitting unit. The sub-light-emitting unit includes: a first semiconductor layer, a second semiconductor layer, a light-emitting layer, a current spreading layer and an insulating layer. The second semiconductor layer is stacked with the first semiconductor layer and has a material different from a material of the first semiconductor layer. The light-emitting layer is located between the first semiconductor layer and the second semiconductor layer. The current spreading layer is located on a side of the first semiconductor layer away from the second semiconductor layer. The insulating layer is located between the current spreading layer and the first semiconductor layer. The current spreading layer and the second semiconductor layer are electrically connected with the first semiconductor layer through a via hole penetrating the insulating layer.

For example, in the light-emitting device provided by at least one embodiment of the present disclosure, a direction along which the first semiconductor layer and the second semiconductor layer are stacked is a longitudinal direction, a plane perpendicular to the longitudinal direction is a horizontal plane, an area of an orthographic projection of the current spreading layer on the horizontal plane is smaller than an area of an orthographic projection of the first semiconductor layer on the horizontal plane, and is located within an orthographic projection of the first semiconductor layer on the horizontal plane.

For example, in the light-emitting device provided by at least one embodiment of the present disclosure, the area of the orthographic projection of the current spreading layer on the horizontal plane is less than ½ of the area of the orthographic projection of the first semiconductor layer on the horizontal plane; and in at least one direction in the horizontal plane, a size of the current spreading layer does not exceed 2 times of a size of the via hole.

For example, in the light-emitting device provided by at least one embodiment of the present disclosure, a direction along which the first semiconductor layer and the second semiconductor layer are stacked is a longitudinal direction, and a plane perpendicular to the longitudinal direction is a horizontal plane; and an orthographic projection of the current spreading layer on the horizontal plane substantially coincides with an orthographic projection of the first semiconductor layer on the horizontal plane.

For example, in the light-emitting device provided by at least one embodiment of the present disclosure, the light-emitting device includes a plurality of the sub-light-emitting units, the plurality of sub-light-emitting units include a first sub-light-emitting unit and a second sub-light-emitting unit; the light-emitting device further includes a bridge electrode, the bridge electrode electrically connects a first semiconductor layer of the first sub-light-emitting unit with a second semiconductor layer of the second sub-light-emitting unit; and a first end of the bridge electrode is electrically connected with the first semiconductor layer of the first sub-light-emitting unit.

For example, in the light-emitting device provided by at least one embodiment of the present disclosure, the first end of the bridge electrode includes an annular part, and the annular part at least partially surrounds a via hole of the first sub-light-emitting unit.

For example, in the light-emitting device provided by at least one embodiment of the present disclosure, the first end of the bridge electrode is in direct contact with at least one of the current spreading layer of the first sub-light-emitting unit and the first semiconductor layer of the first sub-light-emitting unit.

For example, in the light-emitting device provided by at least one embodiment of the present disclosure, in a case where a direction along which the first semiconductor layer and the second semiconductor layer are stacked is a longitudinal direction, and a plane perpendicular to the longitudinal direction is a horizontal plane, an area of an orthographic projection of the current spreading layer on the horizontal plane is smaller than an area of an orthographic projection of the first semiconductor layer on the horizontal plane, and is located within the orthographic projection of the first semiconductor layer on the horizontal plane, the annular part at least partially surrounds the current spreading layer of the first sub-light-emitting unit, and the annular part is in direct contact with the first semiconductor layer of the first sub-light-emitting unit, or the annular part is in direct contact with the insulating layer.

For example, in the light-emitting device provided by at least one embodiment of the present disclosure, a surface of the annular part facing the first semiconductor layer of the first sub-light-emitting unit is in direct contact with a surface of the first semiconductor layer of the first sub-light-emitting unit facing the annular part.

For example, in the light-emitting device provided by at least one embodiment of the present disclosure, in the case where the direction along which the first semiconductor layer and the second semiconductor layer are stacked is the longitudinal direction, the plane perpendicular to the longitudinal direction is the horizontal plane, and the orthographic projection of the current spreading layer on the horizontal plane substantially coincides with the orthographic projection of the first semiconductor layer on the horizontal plane, and the annular part at least partially surrounds the via hole of the first sub-light-emitting unit, and is in contact with the current spreading layer.

For example, in the light-emitting device provided by at least one embodiment of the present disclosure, the surface of the annular part facing the current spreading layer of the first sub-light-emitting unit is in direct contact with the surface of the current spreading layer of the first sub-light-emitting unit facing the annular part.

For example, in the light-emitting device provided by at least one embodiment of the present disclosure, the annular part is a closed annular shape or an unclosed annular shape.

For example, in the light-emitting device provided by at least one embodiment of the present disclosure, a line width in a radial direction of the annular part is greater than a distance from an inner ring of the annular part close to the via hole to a center of the via hole, and the radial direction includes a direction from an annular center of the annular part to a circumference of the annular part.

For example, in the light-emitting device provided by at least one embodiment of the present disclosure, the light-emitting device includes a plurality of the bridge electrodes, the first end of each of the plurality of the bridge electrodes is electrically connected with the first semiconductor layer of the first sub-light-emitting unit, and the first end of at least one of the bridge electrodes includes the annular part.

For example, in the light-emitting device provided by at least one embodiment of the present disclosure, the plurality of bridge electrodes include a first bridge electrode and a second bridge electrode, the first sub-light-emitting unit includes a plurality of via holes, and the plurality of via holes include a first sub-via hole and a second sub-via hole; and both of a first end of the first bridge electrode and a first end of the second bridge electrode include the annular part, the annular part of the first end of the first bridge electrode at least partially surrounds the first sub-via hole, and the annular part of the first end of the second bridge electrode at least partially surrounds the second sub-via hole.

For example, in the light-emitting device provided by at least one embodiment of the present disclosure, in a case where the annular part at least partially surrounds the current spreading layer of the first sub-light-emitting unit, the first sub-light-emitting unit includes a plurality of spreading layers, the plurality of spreading layers include a first spreading layer and a second spreading layer that are electrically connected with the first semiconductor layer of the first sub-light-emitting unit through the first sub-via hole and the second sub-via hole, respectively, the annular part of the first end of the first bridge electrode at least partially surrounds the first spreading layer, and the annular part of the first end of the second bridge electrode at least partially surrounds the second spreading layer.

For example, in the light-emitting device provided by at least one embodiment of the present disclosure, the first sub-light-emitting unit and the second sub-light-emitting unit are arranged along a first direction, the bridge electrode as a whole extends along the first direction; a direction along which the first semiconductor layer and the second semiconductor layer are stacked is a longitudinal direction, and a plane perpendicular to the longitudinal direction is a horizontal plane, for the bridge electrode, the bridge electrode includes a first extension part, an orthographic projection of the first extension part on the horizontal plane is overlapped with an orthographic projection of the first sub-light-emitting unit on the horizontal plane, the first extension part includes a first part and a second part connected with each other; the first semiconductor layer of the first sub-light-emitting unit has a first edge close to the second sub-light-emitting unit, an orthographic projection of the first edge on the horizontal plane is a boundary of an orthographic projection of the first part on the horizontal plane and an orthographic projection of the second part on the horizontal plane, the orthographic projection of the first part on the horizontal plane is overlapped with the orthographic projection of the first semiconductor layer of the first sub-light-emitting unit on the horizontal plane, the orthographic projection of the second part on the horizontal plane is not overlapped with the orthographic projection of the first semiconductor layer of the first sub-light-emitting unit on the horizontal plane; and an extension direction of the first part is substantially perpendicular to the first edge.

For example, in the light-emitting device provided by at least one embodiment of the present disclosure, for the bridge electrode, the bridge electrode includes a second extension part, the second extension part includes a third part and a fourth part connected to each other, the second semiconductor layer of the second sub-light-emitting unit has a second edge close to the first sub-light-emitting unit, an orthographic projection of the second edge on the horizontal plane is a boundary of an orthographic projection of the third part on the horizontal plane and an orthographic projection of the fourth part on the horizontal plane, the orthographic projection of the third part on the horizontal plane is overlapped with the orthographic projection of the second semiconductor layer of the second sub-light-emitting unit on the horizontal plane, the orthographic projection of the fourth part on the horizontal plane is not overlapped with the orthographic projection of the second semiconductor layer of the second sub-light-emitting unit on the horizontal plane; and an extension direction of the third part is substantially perpendicular to the second edge.

For example, in the light-emitting device provided by at least one embodiment of the present disclosure, the first extension part of the bridge electrode includes a first interface part covering the first edge, a second extension part of the bridge electrode includes a second interface part covering the second edge; along the first direction, a thickness of the first interface part in the longitudinal direction is uniform, and a thickness of the second interface part in the longitudinal direction is uniform.

For example, in the light-emitting device provided by at least one embodiment of the present disclosure, the first sub-light-emitting unit and the second sub-light-emitting unit are arranged in the first direction, a length of the first end of the bridge electrode in a second direction is greater than ½ of a length of the first semiconductor layer of the first sub-light-emitting unit in the second direction, and the second direction is perpendicular to the first direction.

For example, in the light-emitting device provided by at least one embodiment of the present disclosure, the bridge electrode includes a connection part and a plurality of branches, a first end of each of the plurality of branches is electrically connected with the first semiconductor layer of the first sub-light-emitting unit, and the first end of each of the plurality of branches are electrically connected with the connection part, the connection part is in direct contact with at least one of the current spreading layer of the first sub-light-emitting unit and the first semiconductor layer of the first sub-light-emitting unit; and a length of the connection part in the second direction is greater than ½ of a length of the first semiconductor layer of the first sub-light-emitting unit in the second direction.

For example, in the light-emitting device provided by at least one embodiment of the present disclosure, the length of the connection part in the second direction is substantially equal to the length of the first semiconductor layer of the first sub-light-emitting unit in the second direction.

For example, in the light-emitting device provided by at least one embodiment of the present disclosure, the connection part is located in an edge region of the first sub-light-emitting unit close to the second sub-light-emitting unit and is in a strip shape extending along the second direction.

For example, in the light-emitting device provided by at least one embodiment of the present disclosure, the light-emitting device is a Mini Light Emitting Diode (referred to as a Mini LED) or a Micro Light Emitting Diode (referred to as a Micro LED); a material of the current spreading layer is a transparent conductive material; the material of the first semiconductor is a P-type semiconductor material, and the material of the second semiconductor is an N-type semiconductor material, or the material of the first semiconductor is an N-type semiconductor material, and the material of the second semiconductor is a P-type semiconductor material.

At least one embodiment of the present disclosure provides a backlight apparatus, includes any one of the light-emitting devices provided by embodiments of the present disclosure.

At least one embodiment of the present disclosure provides an electronic device apparatus, includes any one of the backlight apparatus provided by embodiments of the present disclosure.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1A is a planar schematic diagram of a structure of a light-emitting device provided by an embodiment of the present disclosure;

FIG. 1B is a cross-sectional schematic diagram along a line D-D′in FIG. 1A;

FIG. 2 is a planar schematic diagram of a structure of another light-emitting device provided by an embodiment of the present disclosure;

FIG. 3 is a planar schematic diagram of a structure of still another light-emitting device provided by an embodiment of the present disclosure;

FIG. 4A is a planar schematic diagram of a structure of still another light-emitting device provided by an embodiment of the present disclosure;

FIG. 4B is a cross-sectional schematic diagram along a line D-D′in FIG. 4A;

FIG. 5A is a planar schematic diagram of a structure of still another light-emitting device provided by an embodiment of the present disclosure;

FIG. 5B is a cross-sectional schematic diagram along a line D-D′in FIG. 5A;

FIG. 6A is a planar schematic diagram of a structure of still another light-emitting device provided by an embodiment of the present disclosure;

FIG. 6B is a cross-sectional schematic diagram along a line E-E′ in FIG. 6A;

FIG. 7A is a planar schematic diagram of a structure of still another light-emitting device provided by an embodiment of the present disclosure;

FIG. 7B is a schematic diagram of the current flow of the light-emitting device shown in FIG. 7A;

FIG. 8A is a planar schematic diagram of a structure of still another light-emitting device provided by an embodiment of the present disclosure;

FIG. 8B is a planar schematic diagram of a structure of still another light-emitting device provided by an embodiment of the present disclosure;

FIGS. 9A to 9B are planar schematic diagrams of a structure of still another light-emitting device provided by an embodiment of the present disclosure;

FIG. 10 is a planar schematic diagram of a structure of still another light-emitting device provided by an embodiment of the present disclosure;

FIG. 11 is a planar schematic diagram of a structure of still another light-emitting device provided by an embodiment of the present disclosure;

FIG. 12 is a schematic diagram of a display apparatus provided by an embodiment of the present disclosure; and

FIG. 13 is a schematic diagram of a backlight apparatus provided by an embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. The described embodiments are just a part but not all of the embodiments of the present disclosure. Based on the described embodiments herein, those skilled in the art can obtain other embodiment(s), without any inventive efforts, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” or “include,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the absolute position of the object which is described is changed, the relative position relationship may be changed accordingly.

Characteristics such as “parallel”, “perpendicular” and “identical” used in this disclosure include “parallel”, “perpendicular”, “identical” and other characteristics in the strict sense, as well as “substantially parallel”, “substantially overlapping”, “substantially identical” and so on and other situations that contain certain errors, taking into account the errors in the measurement and associated with the measurement of the particular quantity (for example, limitations of the measurement system), which means they are within an acceptable range of deviations for a particular value as determined by one of ordinary skilled in the art. For example, “substantially” can mean they are within one or more standard deviations, and unless otherwise specified, can mean they are within a 10% or 5% deviation range of the stated value.

In display apparatuses or backlight modules using current-driven light-emitting diodes (LEDs), as the pitches between adjacent LEDs become smaller and smaller, and the current used becomes smaller and smaller, the LEDs will operate in an unstable state and have low luminous efficiency.

At least one embodiment of the present disclosure provides a light-emitting device, which includes a sub-light-emitting unit, and the sub-light-emitting unit includes a first semiconductor layer, a second semiconductor layer, a light-emitting layer, a current spreading layer and an insulating layer. The second semiconductor layer is stacked with the first semiconductor layer and is made of a material different from a material of the first semiconductor layer; the light-emitting layer is located between the first semiconductor layer and the second semiconductor layer; the current spreading layer is located on a side of the first semiconductor layer away from the second semiconductor layer; the insulating layer is located between the current spreading layer and the first semiconductor layer, and the current spreading layer and the second semiconductor layer are electrically connected with the first semiconductor layer through a via hole penetrating the insulating layer.

At least one embodiment of the present disclosure further provides a display apparatus, and the display apparatus includes any one of the light-emitting devices provided by the embodiments of the present disclosure.

At least one embodiment of the present disclosure also provides a backlight apparatus, and the backlight apparatus includes any one of the light-emitting devices provided by the embodiments of the present disclosure.

At least one embodiment of the present disclosure also provides an electronic equipment, and the electronic equipment includes any one of the backlight apparatus provided by the embodiments of the present disclosure.

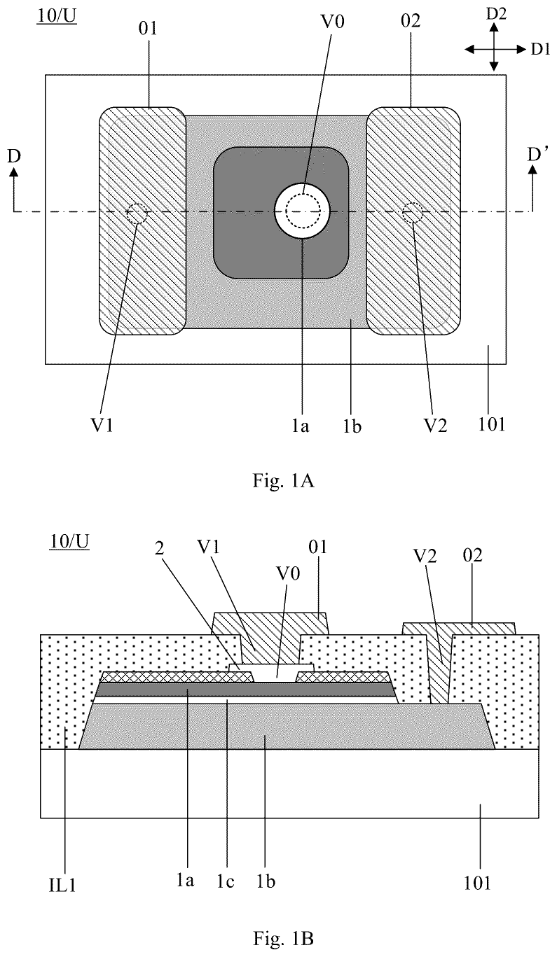

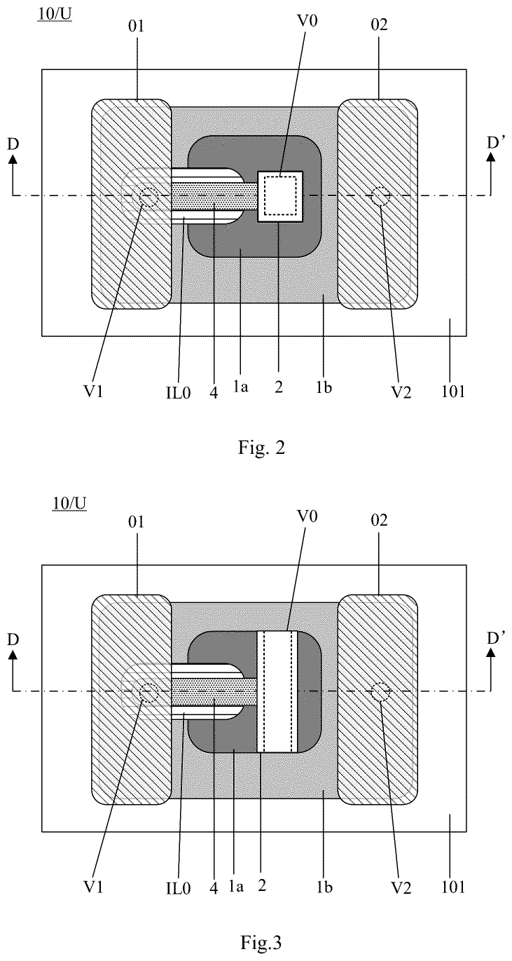

Exemplarily, FIG. 1A is a planar schematic diagram of a structure of a light-emitting device provided by an embodiment of the present disclosure, and FIG. 1B is a cross-sectional schematic diagram along a line D-D′in FIG. 1A. Referring to FIGS. 1A to 1B, the light-emitting device 10 provided by the present disclosure includes a sub-light-emitting unit U, and the sub-light-emitting unit U includes a first semiconductor layer 1a, a second semiconductor layer 1b, a light-emitting layer 1c, a current spreading layer 2 and a second insulating layer IL2 (that is, a second insulating layer IL2). The second semiconductor layer 1b is stacked with the first semiconductor layer 1a and is made of a material different from a material of the first semiconductor layer 1a; the light-emitting layer 1c is located between the first semiconductor layer 1a and the second semiconductor layer 1b; the current spreading layer 2 is located on a side of the first semiconductor layer 1a away from the second semiconductor layer 1b; the second insulating layer IL2 is located between the current spreading layer 2 and the first semiconductor layer 1a, and the current spreading layer 2 is electrically connected with the first semiconductor layer 1a through a via hole V0 penetrating the second insulating layer IL2. An effective light-emitting region of the light-emitting device 10 is a region where an operating current is mainly distributed and a region where light is emitted, the effective light-emitting region is substantially the region where the current spreading layer 2 directly contacts with the first semiconductor layer 1a, or a region slightly larger than the region where the current spreading layer 2 directly contacts with the first semiconductor layer 1a, therefore, the effective light-emitting area can be represented by an area of the part where the current spreading layer 2 is in direct contact with the first semiconductor layer 1a, thus in the light-emitting device 10 provided by the embodiment of the present disclosure, since the current spreading layer 2 is electrically connected with the first semiconductor layer 1a through the via hole V0 penetrating the second insulating layer IL2, the part of the current spreading layer 2 that is in direct contact with the first semiconductor layer 1a is only a part of the current spreading layer 2 located in the via hole V0, the area of this part is small, is substantially equal to a range of a shape of an orthographic projection of the via hole V0 on the horizontal plane, thus, an area of the part where the current spreading layer 2 is in direct contact with the first semiconductor layer 1a is reduced, therefore, the effective light-emitting area of the light-emitting device 10 is reduced. Current density=I/S, I is an operating current when the light-emitting device 10 emits light, and S is an effective light-emitting area of the light-emitting device 10; since the effective light-emitting area S is reduced in the light-emitting device 10 provided by the embodiment of the present disclosure, the current density during the operation of the light-emitting device 10 is improved, so that the light-emitting device 10 is made to operate in a stable state, and the light-emitting efficiency is improved.

It should be noted that the area of the part of the current spreading layer 2 that is in direct contact with the first semiconductor layer 1a refers to an area of an orthographic projection of the part of the current spreading layer 2 that is in direct contact with the first semiconductor layer 1a on the horizontal plane, the direction along which the first semiconductor layer 1a and the second semiconductor layer 1b are stacked is a longitudinal direction, and the plane perpendicular to the longitudinal direction is a horizontal plane.

For example, the light-emitting device 10 further includes a base substrate 101, the first semiconductor layer 1a and the second semiconductor layer 1b are stacked on a main surface of the base substrate 101. For example, the base substrate 101 can be a sapphire substrate, a GaAs substrate, a GaN substrate, a SiC substrate, a Si substrate, a glass substrate, a quartz substrate, the embodiment of the present disclosure does not limit the material of the base substrate, and those skilled in the art can select it as needed.

For example, the light-emitting device 10 is a Mini Light Emitting Diode (referred to as a Mini LED) or a Micro Light Emitting Diode (referred to as a Micro LED). For example, a size of the Mini Light Emitting Diode (referred to as the Mini LED) is approximately 100 μm to 300 μm. A size of the Micro Light Emitting Diode (referred as the Micro LED for short) is less than 100 μm. For example, the first semiconductor material is a P-type semiconductor material, and the second semiconductor material is an N-type semiconductor material. Alternatively, the first semiconductor material is an N-type semiconductor material, and the second semiconductor material is a P-type semiconductor material. Electrons and holes are combined in the light-emitting layer 1c driven by current, to convert electrical energy into light energy to emit light.

For example, the material of the current spreading layer 2 is a transparent conductive material, which can transmit the light emitted by the light-emitting layer 1c. The transparent conductive material can be indium tin oxide (ITO), indium zinc oxide (IZO), zinc oxide, aluminum zinc oxide, gallium zinc oxide, etc., but are not limited to the above listed types, and the embodiments of the present disclosure do not limit the types of transparent conductive materials.

Referring to FIG. 1A, for example, a shape of an orthographic projection of the via hole V0 on the horizontal plane may be point-like. For example, a size of an orthographic projection shape of the via hole V0 on the horizontal plane in the first direction D1 is equal to a size of an orthographic projection shape of the via hole V0 on the horizontal plane in the second direction D2, and the first direction D1 is perpendicular to the second direction D2. For example, the shape of the orthographic projection of via hole V0 on the horizontal plane is circular, the circular via hole V0 can make the effective light-emitting region emit light more uniformly in all directions. Of course, the shape of the orthographic projection of the via hole V0 on the horizontal plane is a regular shape or an irregular shape, and the regular shape includes at least one of circular, polygonal and elliptical.

For example, the size of the orthographic projection shape of the via hole V0 on the horizontal plane in the first direction D1 is less than ¼ of the size of the first semiconductor layer 1a in the first direction D1, and the size of the orthographic projection shape of the via hole V0 on the horizontal plane in the second direction D2 is less than ¼ of the size of the first semiconductor layer 1a in the first direction D1, so that the opening area of the via hole V0 is smaller, and thus it is ensured that the effective light-emitting area of the light-emitting device 10 is small.

Referring to FIG. 2, for example, the shape of the orthographic projection of the via hole V0 on the horizontal plane can also be a polygon, such as a rectangle, in this case, the size of the orthographic projection shape of the via hole V0 on the horizontal plane in the first direction D1 is smaller than the size of the first semiconductor layer 1a in the first direction D1. Of course, the shape of the orthographic projection of the via hole V0 on the horizontal plane can also be a square, or other polygons, such as a triangle, a pentagon, etc., and the shape of the orthographic projection of the via hole V0 on the horizontal plane is not limited to the above-mentioned types.

Referring to FIG. 3, for example, the shape of the orthographic projection of the via hole V0 on the horizontal plane is a long strip; for example, the size of the orthographic projection shape of the via hole V0 on the horizontal plane in the first direction D1 is less than ½ of the size of the first semiconductor layer 1a in the first direction D1, even the size of the orthographic projection shape of the via hole V0 on the horizontal plane in the first direction D1 is smaller than ¼ of the size of the first semiconductor layer 1a in the first direction D1.

Other features of FIGS. 2 and 3 are the same as those of the embodiment shown in FIGS. 1A to 1B, which can refer to the previous descriptions.

FIGS. 1A to 1B, for example, an area of the orthographic projection of the current spreading layer 2 on the horizontal plane is smaller than an area of the orthographic projection of the first semiconductor layer 1a on the horizontal plane, and is located within the orthographic projection of the first semiconductor layer 1a on the horizontal plane, so as to effectively reduce the area of the current spreading layer 2, therefore, a space range in which the current can be expanded is limited, which facilitates reducing the effective light-emitting area of the light-emitting device 10, increasing the current density of the light-emitting device 10, and improving the light-emitting efficiency of the light-emitting device 10.

Referring to FIGS. 1A to 1B, for example, the area of the orthographic projection of the current spreading layer 2 on the horizontal plane is less than ½ of the area of the orthographic projection of the first semiconductor layer 1a on the horizontal plane; furthermore, in at least one direction in the horizontal plane, the size of the current spreading layer 2 does not exceed two times of the size of the via hole V0; for example, in both the first direction D1 and the second direction D2, the size of the current spreading layer 2 does not exceed two times of the size of the via hole V0, so as to further reduce the area of the current spreading layer 2, therefore, the space range in which the current can be expanded is limited, which facilitate reducing the effective light-emitting area of the light-emitting device 10, increasing the current density of the light-emitting device 10, and improving the light-emitting efficiency of the light-emitting device 10.

Referring to FIG. 1A, for example, the shape of the orthographic projection of the current spreading layer 2 on the horizontal plane is substantially the same as the shape of the orthographic projection of the via hole V0 on the horizontal plane and remains consistent. For example, in FIG. 1A, both are circular, but of course they can also be in other shapes. In this way, the operating current I of the light-emitting device 10 is evenly distributed in all directions, fully ensuring consistency of the light-emitting performance of the current spreading layer 2 in all directions, which facilitates fully improving the light-emitting efficiency of the effective luminous region in all directions, improving the overall light-emitting efficiency of the light-emitting device, and avoiding the problem of low light-emitting efficiency in some positions due to uneven distribution of the operating current I.

Referring to FIG. 1B, for example, the light-emitting device 10 includes a first electrode 01 and a second electrode 02. The first electrode 01 is electrically connected with the current spreading layer 2; the second electrode 02 is electrically connected with the second semiconductor layer 1b, and an orthographic projection of the first electrode 01 on the horizontal plane and an orthographic projection of the first semiconductor layer 1a on the horizontal plane are at least partially overlapped, and the first electrode 01 and the current spreading layer 2 are directly electrically connected through the first via hole V1 instead of implementing the electrical connection, for example, through an internal bridge electrode. For example, there are no other conductive structures between the first electrode 01 and the first semiconductor layer 1a, the first electrode 01 and the first semiconductor layer 1a are not electrically connected through other structures such as internal bridge electrodes, compared with the embodiment of FIGS. 5A to 5B described below, the internal bridge electrode and the interlayer insulating layer used to insulate the internal bridge electrode from the second semiconductor layer are removed, thus the structure of the light-emitting device 10 is simplified, thus a flat structure can be formed on the surface of the first semiconductor layer 1a away from the second semiconductor layer 1b (that is, above the first semiconductor layer 1a), the ejector pin used to transfer the light-emitting device can be used to act on the flat structure, to reduce damage to the structure of the platform above the first semiconductor layer 1a and the first semiconductor layer 1a.

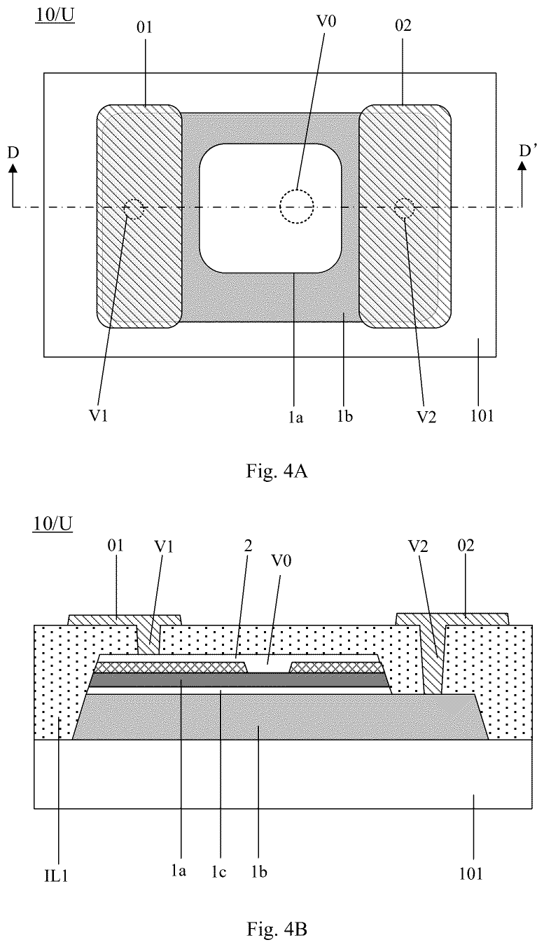

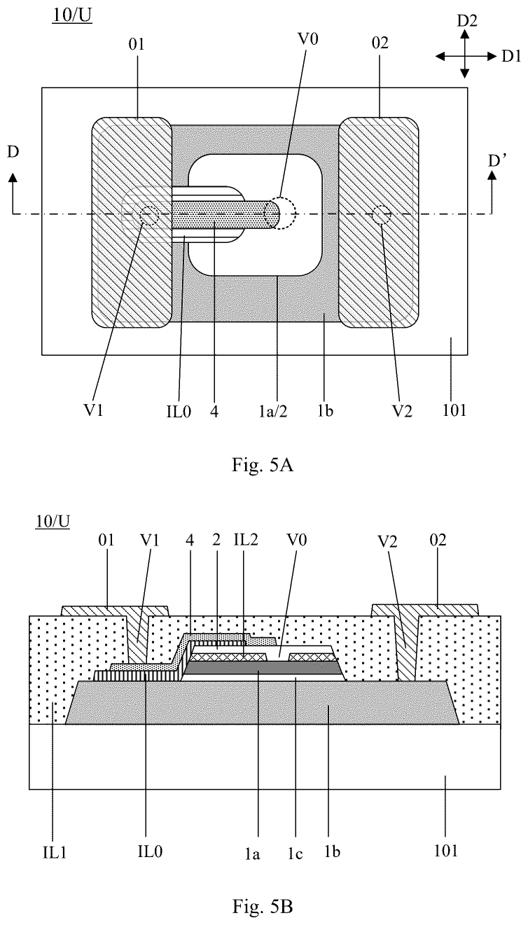

FIG. 4A is a planar schematic diagram of a structure of still another light-emitting device provided by an embodiment of the present disclosure; and FIG. 4B is a cross-sectional schematic diagram along a line D-D′in FIG. 4A. The light-emitting device shown in FIGS. 4A to 4B and the light-emitting device shown in FIGS. 1A to 1B have the following differences.

Referring to FIGS. 4A to 4B, for example, the orthographic projection of the current spreading layer 2 on the horizontal plane substantially coincides with the orthographic projection of the first semiconductor layer 1a on the horizontal plane, that is, the orthographic projection of the current spreading layer 2 on the horizontal plane and the orthographic projection of the first semiconductor layer 1a on the horizontal plane have a same shape, a same size, and are overlapped with each other. In this case, since the current spreading layer 2 is only electrically connected with the first semiconductor layer 1a through the via hole V0 penetrating the second insulating layer IL2, instead of an entire surface of the current spreading layer 2 facing the first semiconductor layer 1a being in contact with the first semiconductor layer 1a, therefore, a region of the light-emitting device 10 where the operating current is distributed is only the region where the current spreading layer 2 is in direct contact with the first semiconductor layer 1a, or a region slightly larger than the part where the current spreading layer 2 is in direct contact with the first semiconductor layer 1a, while the operating current will not extend to the entire current spreading layer 2, therefore, in the case where the orthographic projection of the current spreading layer 2 on the horizontal plane substantially coincides with the orthographic projection of the first semiconductor layer 1a on the horizontal plane, the effective light-emitting area of the light-emitting device 10 can also be reduced, the current density of the light-emitting device 10 can be increased, and the light-emitting efficiency of the light-emitting device 10 can be improved.

Other structures and corresponding technical effects of the light-emitting device shown in FIGS. 4A to 4B are the same as those of the light-emitting device shown in FIGS. 1A to 1B, and the descriptions of the light-emitting devices shown in FIGS. 1A to 1B can be referred.

FIG. 5A is a planar schematic diagram of a structure of still another light-emitting device provided by an embodiment of the present disclosure; and FIG. 5B is a cross-sectional schematic diagram along a line D-D′in FIG. 5A. The light-emitting device shown in FIGS. 5A to 5B and the light-emitting device shown in FIGS. 4A to 4B have the following differences.

Referring to FIGS. 5A to 5B, for example, the light-emitting device 10 further includes a first electrode 01, a second electrode 02 and a first insulating layer IL1. The first electrode 01 is electrically connected with the current spreading layer 2 through the first via hole V1 penetrating the first insulating layer IL1; the second electrode 02 is electrically connected with the second semiconductor layer 1b through the second via hole V2 penetrating the first insulating layer IL1. For example, the light-emitting device 10 further includes an internal bridge electrode 4, the internal bridge electrode 4 is located on the side of the first semiconductor layer 1a away from the second semiconductor layer 1b, and is insulated from the second semiconductor layer 1b by the interlayer insulating layer IL0; the first electrode O1 is electrically connected with the internal bridge electrode 4 through the first via hole V1, and the internal bridge electrode 4 is electrically connected with the first semiconductor layer 1a, for example, the internal bridge electrode 4 is directly in contact with and connected with the surface of the first semiconductor layer 1a away from the base substrate 101, thus the first electrode 01 is electrically connected with the first semiconductor layer 1a through the internal bridge electrode 4. The light-emitting device 10 provided in this embodiment can achieve a same technical effect as shown in FIGS. 4A to 4B in terms of reducing the effective light-emitting area and improving the light-emitting efficiency.

Other structures and corresponding technical effects of the light-emitting device shown in FIGS. 5A to 5B are the same as those of the light-emitting device shown in FIGS. 4A to 4B, and the descriptions of the light-emitting device shown in FIGS. 4A to 4B can be referred.

The above embodiment shows the case where the light-emitting device 10 only includes one sub-light-emitting unit U, that is, the light-emitting device 10 is a single LED light-emitting chip. The following describes a case where a light-emitting device includes a plurality of sub-light-emitting units U.

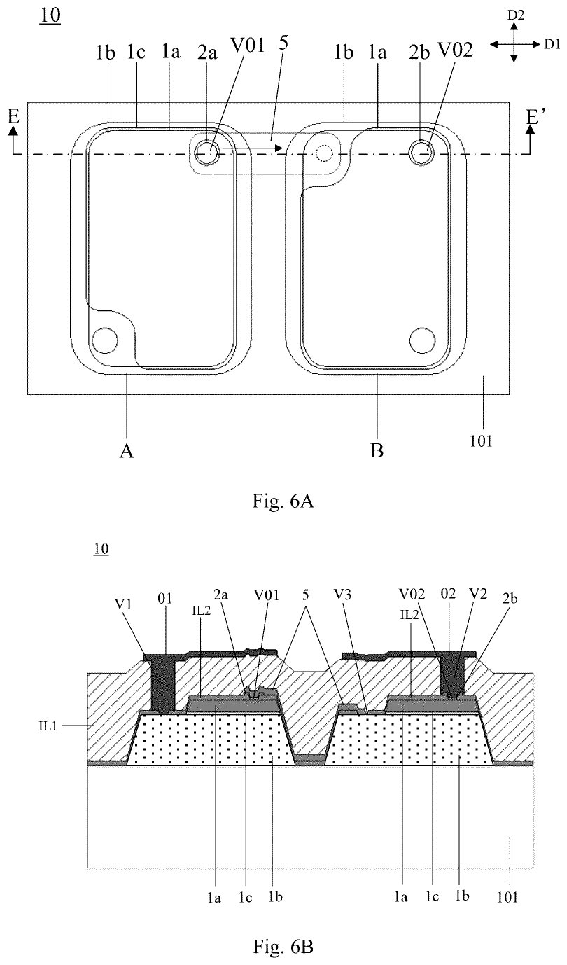

FIG. 6A is a planar schematic diagram of a structure of still another light-emitting device provided by an embodiment of the present disclosure; and FIG. 6B is a cross-sectional schematic diagram along a line E-E′ in FIG. 6A. The light-emitting device shown in FIGS. 6A to 6B has the following differences from the light-emitting device shown in FIGS. 1A to 1B.

Referring to FIGS. 6A to 6B, the light-emitting device 10 includes a plurality of sub-light-emitting units, for example, the plurality of sub-light-emitting units include a first sub-light-emitting unit A and a second sub-light-emitting unit B; the light-emitting device 10 further includes a bridge electrode 5, which electrically connects the first semiconductor layer 1a of the first sub-light-emitting unit A and the second semiconductor layer 1b of the second sub-light-emitting unit B; a first end of the bridge electrode 5 is electrically connected with the first semiconductor layer 1a of the first sub-light-emitting unit A, so that a PN junction of the first sub-light-emitting unit A and a PN junction of the second sub-light-emitting unit B are connected in series, and a high-voltage light-emitting device, such as a high-voltage Mini LED or a high-voltage Micro LED, is constructed.

Referring to FIGS. 6A to 6B, for example, in the first sub-light-emitting unit A and the second sub-light-emitting unit B, the situation is similar to FIGS. 1A to 1B, the current spreading layer is electrically connected with the first semiconductor layer 1a through a via hole penetrating the second insulating layer IL2. In the first sub-light-emitting unit A, the current spreading layer 2a is electrically connected with the first semiconductor layer 1a through the first sub-via hole V01 penetrating the second insulating layer IL2, and in the second sub-light-emitting unit B, the current spreading layer 2b is electrically connected with the first semiconductor layer 1a through the second sub-via hole V02 penetrating the second insulating layer IL2, to reduce the effective light-emitting area of each of the sub-light-emitting units and increase the current density, therefore, the light-emitting device can be operated in a stable state, and the light-emitting efficiency can be improved.

A first end of the bridge electrode 5 is in direct contact with at least one of the current spreading layer 2 of the first sub-light-emitting unit A and the first semiconductor layer 1a of the first sub-light-emitting unit A. For example, as shown in FIG. 6B, in the first sub-light-emitting unit A, in the case where an area of an orthographic projection of the current spreading layer 2 on the horizontal plane is smaller than an area of an orthographic projection of the first semiconductor layer 1a on the horizontal plane, and is located within the orthographic projection of the first semiconductor layer 1a on the horizontal plane, the first end of the bridge electrode 5 is in direct contact with the current spreading layer 2a of the first sub-light-emitting unit A to achieve electrically connection, thus, the first end of the bridge electrode 5 is electrically connected with the first semiconductor layer 1a of the first sub-light-emitting unit A; for example, in the second sub-light-emitting unit B, the second electrode 02 is in direct contact with the current spreading layer 2b of the second sub-light-emitting unit B through the via hole V2 penetrating the first insulating layer IL1 to achieve electrically connection.

As the effective light-emitting area is reduced, the electrostatic discharge (ESD) capability of the light-emitting device decreases sharply, this is, an actual position where ESD occurs usually occurs in the effective light-emitting region, that is, the positions of the first sub-via holes V01 and V02, and the positions of the first sub-via holes V01 and V02 are prone to breakdown. For example, in FIG. 6A, the first sub-light-emitting unit A and the second sub-light-emitting unit B are arranged in the first direction D1, a planar pattern of the bridge electrode 5 is in a shape of a strip extending along the first direction D1. After testing, it has been found that the electrostatic charge accumulated at the via hole V01 is substantially conducted from the via hole V01 along the first direction and is released (a direction indicated by a black arrow marked on the bridge electrode 5 in FIG. 6A), and the current from electrostatic discharge will flow in a path of lowest resistance, since the light-emitting region is made of transparent conductive materials such as ITO, ITO has poor conductivity compared to metals, and a single path can easily cause charge accumulation, and ESD breakdown of an operation film layer where the via hole V0 is located is avoided.

For other unmentioned structures of each of the sub-light-emitting units in FIGS. 6A to 6B, the descriptions of a single sub-light-emitting unit in the previous embodiments can be referred.

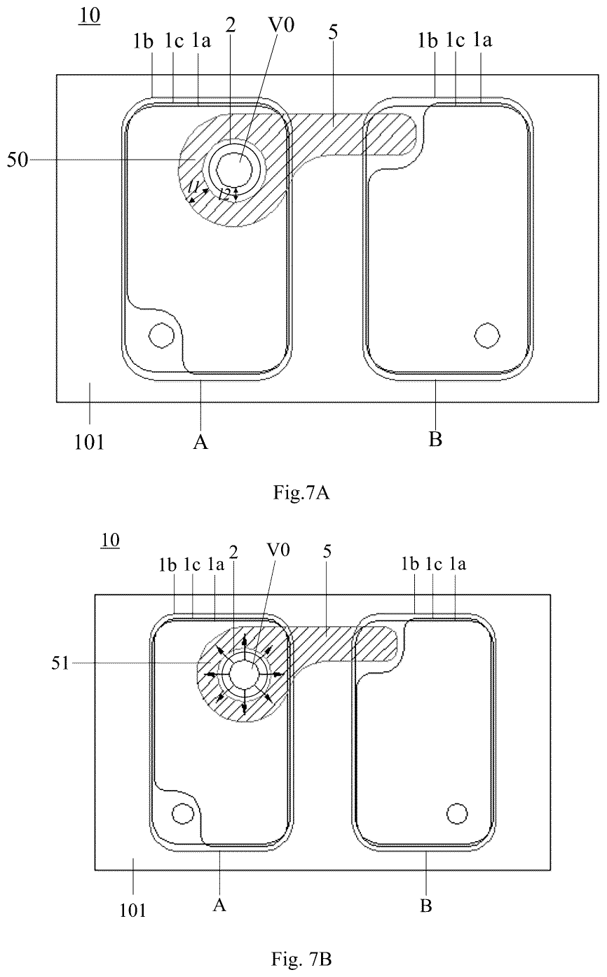

FIG. 7A is a planar schematic diagram of a structure of still another light-emitting device provided by an embodiment of the present disclosure; and FIG. 7B is a schematic diagram of the current flow of the light-emitting device shown in FIG. 7A. The light-emitting device shown in FIGS. 7A to 7B has the following differences from the light-emitting device shown in FIGS. 6A to 6B.

Referring to FIG. 7A, for example, a first end of the bridge electrode 5 includes an annular part 50, the annular part 50 at least partially surrounds the above-mentioned via hole V0 of the first sub-light-emitting unit A. In this way, referring to FIG. 7B, during a release process of the static electricity accumulated at the via hole V0, a current path can flow evenly around the via hole V0, that is, the current can be radiated in radial directions (the directions indicated by a plurality of arrows in FIG. 7B) through the annular part 50 surrounding the via hole V0, so that the static electricity is quickly released, the ESD performance of the light-emitting device 10 is improved, the above-mentioned problem of poor ESD performance can be effectively alleviated or avoided, and ESD breakdown of the operation film layer where the via hole V0 is located can be avoided.

For example, in FIG. 7A, the annular part 50 surrounds the entire via hole V0, in this case, the annular part is a closed annular shape to improve the electrostatic discharge capability in all directions around the via hole V0, the electrostatic discharge effect is better ensured and the above-mentioned problem of poor ESD performance is effectively alleviated or avoided, and it is better to avoid ESD breakdown on the operation film layer where the via hole V0 is located. Or in other embodiments, the annular part may be an unclosed annular shape, and can still effectively improve the ESD capability of the effective light-emitting region where the via hole V0 of the light-emitting device is located.

As shown in FIG. 7A, in the case where the area of the orthographic projection of the current spreading layer 2 on the horizontal plane is smaller than the area of the orthographic projection of the first semiconductor layer 1a on the horizontal plane, and is located within the orthographic projection of the first semiconductor layer 1a on the horizontal plane, for example, the annular part 50 at least partially surrounds the current spreading layer 2 of the first sub-light-emitting unit A, and is in direct contact with the first semiconductor layer 1a of the first sub-light-emitting unit A, that is, the annular part 50 is in direct contact with a part of the first semiconductor layer 1a of the first sub-light-emitting unit A that is exposed by the current spreading layer 2 and the second insulating layer IL2, to reduce a connection resistance between the bridge electrode 5 and the first semiconductor layer 1a of the first sub-light-emitting unit A. For example, a surface (for example, an entire surface) of the annular part 50 facing the first semiconductor layer 1a of the first sub-light-emitting unit A is in direct contact with a surface of the first semiconductor layer 1a of the first sub-light-emitting unit A facing the annular part.

Or, in other embodiments, in the case where the area of the orthographic projection of the current spreading layer 2 on the horizontal plane is smaller than the area of the orthographic projection of the first semiconductor layer 1a on the horizontal plane, and is located within the orthographic projection of the first semiconductor layer 1a on the horizontal plane, a second insulating layer IL2 is provided between the annular part 50 and the first semiconductor layer 1a of the first sub-light-emitting unit A.

For example, in other embodiments, in the case where the orthographic projection of the current spreading layer 2 on the horizontal plane substantially coincides with the orthographic projection of the first semiconductor layer 1a on the horizontal plane, the annular part at least partially surrounds the via hole V0 of the first sub-light-emitting unit A and is in contact with the current spreading layer 2. For example, the surface of the annular part facing the current spreading layer 2 of the first sub-light-emitting unit A is in direct contact with the surface of the current spreading layer 2 of the first sub-light-emitting unit A facing the annular part, for example, the two surfaces are bonded to each other.

For example, referring to FIG. 7A, a line width l1 in a radial direction of the annular part 50 is greater than a distance l2 from an inner ring of the annular part 50 close to the via hole V0 to the center of the via hole V0, to effectively ensure sufficient hole diameter for electrostatic discharge and improve the effect of ESD. The radial direction refers to a direction from the center of the annular part 50 to a circumference of the annular part 50, that is, the direction from the via hole V0 to the annular part 50.

At least part of an outer contour shape of the annular part 50 is substantially the same as a shape of an orthographic projection of the via hole V0 on the horizontal plane, for example, they are concentric rings, for example, they are circular rings in a whole, or they are all rectangular rings, elliptical rings, etc., the embodiments of the present disclosure do not limit the specific shapes of the annular part and the via hole.

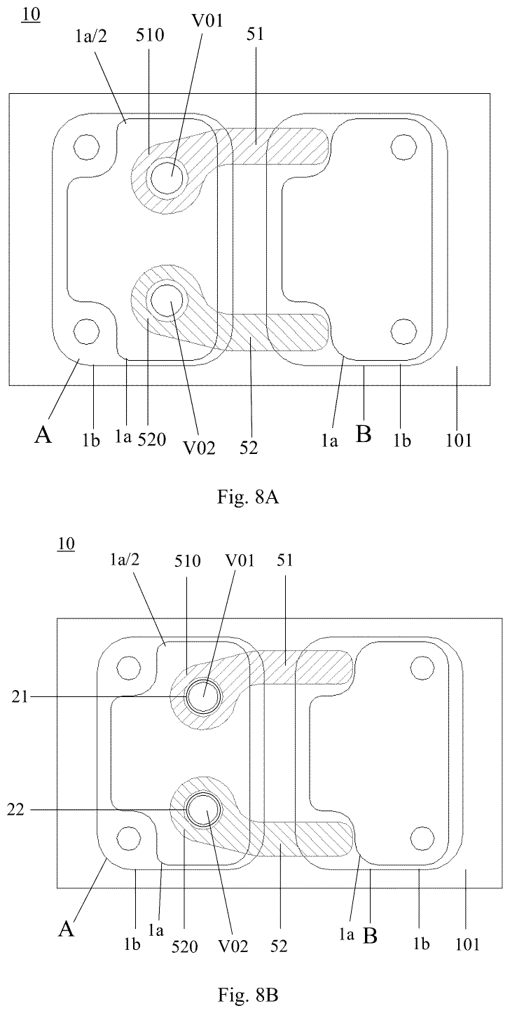

FIG. 8A is a planar schematic diagram of a structure of still another light-emitting device provided by an embodiment of the present disclosure. The light-emitting device shown in FIG. 8A has the following differences from the light-emitting devices shown in FIGS. 7A to 7B.

Referring to FIG. 8A, the light-emitting device 10 includes a plurality of bridge electrodes, a first end of each of the plurality of bridge electrodes 5 is electrically connected with the first semiconductor layer 1a of the first sub-light-emitting unit A, for example, a second end of each of the plurality of bridge electrodes 5 opposite to the first end is electrically connected with the second semiconductor layer 1b of the second sub-light-emitting unit B. In this way, the plurality of bridge electrodes connected in parallel can reduce a resistance of the signal transmission path between two sub-light-emitting units electrically connected through the plurality of bridge electrodes, so that the signal efficiency is improved, and the disadvantages caused by heating caused by resistance are reduced.

For example, a first end of at least one bridge electrode of the plurality of bridge electrodes includes the above-mentioned annular part, here, the characteristics and corresponding technical effects of each of the annular parts are the same as in the previous embodiments, the previous descriptions can be referred, which will not be repeated herein.

Referring to FIG. 8A, for example, the plurality of bridge electrodes include a first bridge electrode 51 and a second bridge electrode 52, a first end of the first bridge electrode 51 and a first end of the second bridge electrode 52 are both electrically connected with the first semiconductor layer 1a of the first sub-light-emitting unit A, for example, the second end of each of the plurality of bridge electrodes 5 opposite to the first end is electrically connected with the second semiconductor layer 1b of the second sub-light-emitting unit B.

Referring to FIG. 8A, for example, the first bridge electrode 51 and the second bridge electrode 52 may respectively have the same structure as the single bridge electrode 5 in the previous embodiments. The first sub-light-emitting unit A includes a plurality of via holes with a same structure as the above-mentioned via hole V0, the structures of the first semiconductor layer 1a, the second semiconductor layer 1b, the light-emitting layer and the second insulating layer of the first sub-light-emitting unit A are the same as those in the embodiment shown in FIGS. 7A to 7B. For example, referring to FIG. 8A, the plurality of via holes include a first sub-via hole V01 and a second sub-via hole V02, the light-emitting device 10 shown in FIG. 8A also includes a second insulating layer located between the current spreading layer 2 and the first semiconductor layer 1a; in the first sub-light-emitting unit A, the current spreading layer 2 is electrically connected with the first semiconductor layer 1a through the first sub-via hole V01 penetrating the second insulating layer and the second sub-via hole V02 penetrating the second insulating layer; the first end of the first bridge electrode 51 and the first end of the second bridge electrode 52 both include an annular part, the annular part 510 of the first end of the first bridge electrode 51 at least partially surrounds the first sub-via hole V01 of the first sub-light-emitting unit A, and the annular part of the first end of the second bridge electrode 52 at least partially surrounds the second sub-via hole V02 of the first sub-light-emitting unit A. Thus, for each of the effective light-emitting regions, that is, substantially, an area where each of the first sub-via hole V01 and the second sub-via hole V02 that penetrate the second insulating layer is located, it can enhance its ESD capability, and the operation film layer in each of the effective light-emitting regions is effectively prevented from being electrically broken down.

Other characteristics of the embodiment shown in FIG. 8A that are not mentioned are the same as those of FIGS. 7A to 7B.

FIG. 8B is a planar schematic diagram of a structure of still another light-emitting device provided by an embodiment of the present disclosure. The light-emitting device shown in FIG. 8B has the following differences from the light-emitting device shown in FIG. 8A.

Referring to FIG. 8B, in the case where the light-emitting device in the FIG. 8B includes a plurality of bridge electrodes, the first sub-light-emitting unit A includes a plurality of spreading layers, the plurality of spreading layers include a first spreading layer 21 and a second spreading layer 22 that are electrically connected with the first semiconductor layer 1a of the first sub-light-emitting unit A through the first sub-via hole V01 and the second sub-via hole V02 respectively, areas of orthographic projections of the first spreading layer 21 and the second spreading layer 22 on the horizontal plane are both smaller than an area of the orthographic projection of the first semiconductor layer 1a on the horizontal plane, for example, are less than ½ of the area of the orthographic projection of the first semiconductor layer 1a on the horizontal plane, for example, less than ¼ of the area of the orthographic projection of the first semiconductor layer 1a on the horizontal plane, in short, they are all much smaller than the area of the orthographic projection of the first semiconductor layer 1a on the horizontal plane, and the orthographic projections of the first spreading layer 21 and the second spreading layer 22 on the horizontal plane are both located within the orthographic projection of the first semiconductor layer 1a on the horizontal plane, an annular part of a first end of the first bridge electrode 51 at least partially surrounds the first spreading layer 21, and an annular part of a first end of the second bridge electrode 52 at least partially surrounds the second spreading layer 22. That is, in a sub-light-emitting unit, the plurality of via holes V01/V02 penetrating the second insulating layer respectively correspond to a plurality of sub-current spreading layers, in other words, in a sub-light-emitting unit, the current spreading layer 2 includes a plurality of parts corresponding to the plurality of via holes V01/V02 penetrating the second insulating layer. Thus, for each of the sub-spreading layers such as the first spreading layer 21 and the second spreading layer 22, it is not only beneficial to improve efficiency of electrostatic discharge in the parts of the first spreading layer 21 and the second spreading layer 22 respectively located in the corresponding via holes V01/V02, and but also makes it easy to efficiently realize electrostatic discharge in the parts of the entire first spreading layer 21 and the second spreading layer 22 located outside the corresponding via holes V01/V02, therefore, for each of the spreading layers, the effective light-emitting region where the entire spreading layer is located can easily and efficiently realize electrostatic discharge.

Other unmentioned characteristics of the light-emitting device shown in FIG. 8B are the same as those in FIG. 8A.

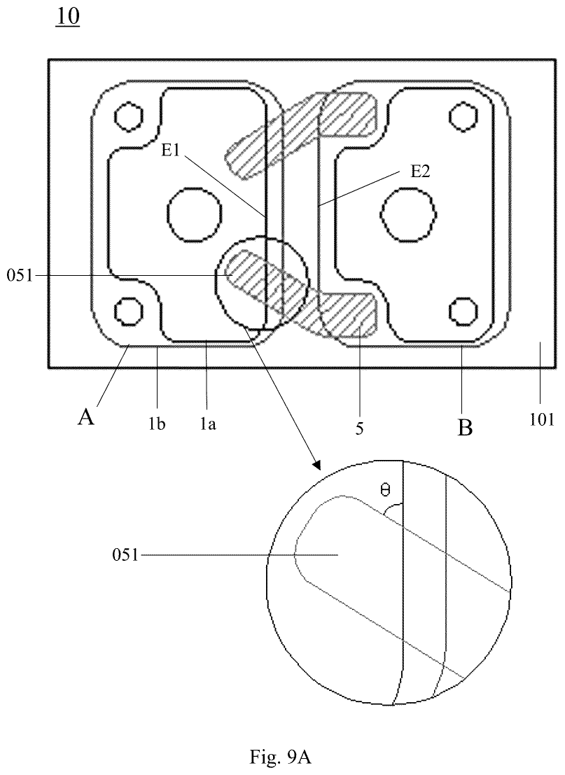

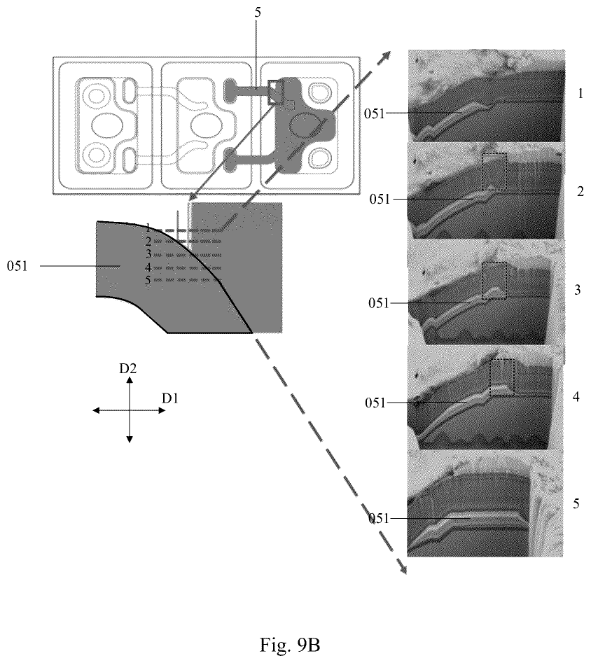

FIG. 9A is a planar schematic diagram of a structure of still another light-emitting device provided by an embodiment of the present disclosure. In FIG. 9A, the first semiconductor layer 1a of the first sub-light-emitting unit A has a first edge E1 close to the second sub-light-emitting unit B, an angle θ between the extension direction of the bridge part 051 of the bridge electrode 5 across the first edge E1 and the first edge E1 is an acute angle, therefore, starting from a position where the bridge part 051 is overlapped with the first edge E1, along the first direction D1, the bridge part 051 has a part in which an overlapping area with the first semiconductor layer 1a of the first sub-light-emitting unit A gradually increases. FIG. 9B shows the analysis of 5 cross-sections (dashed lines) of No. 1 to 5 on the left side, and the 5 cross-sections are shown in the electron microscopy images on the right side of No. 1 to 5 in sequence. As shown in FIG. 9B, in this part, during the process of manufacturing the bridge electrode 5, for example, in the process of forming the bridge electrode 5 through a deposition process or the like, it is very easy to form discontinuous islands near the position where the bridge part 051 is overlapped with the first edge E11, and the bridge part 051 is likely to have a tip protrusion near this position. There is a tip protrusion of the bridge part 051 in the dotted box in FIG. 9B, furthermore, in No. 1 to No. 4, a right side of the bridge part 051 is discontinuous, and a thickness of the entire bridge part 051 is uneven. Until the lowest position, as shown in the cross-section diagram of No. 5, the thickness of the bridge part 051 at the No. 5 cross-section line position becomes relatively uniform. In this way, the film layers such as the second insulating layer formed on the tip protrusion are very prone to cracking, which affects the insulation effect and leads to leakage, moreover, sealing performance of the light-emitting device is poor, which brings serious problems to the performance of the light-emitting device. Similarly, the second semiconductor layer 1b of the second sub-light-emitting unit B has a second edge E2 close to the first sub-light-emitting unit A, the same applies to the part where the second end of the bridge electrode 5 crosses the second edge E2.

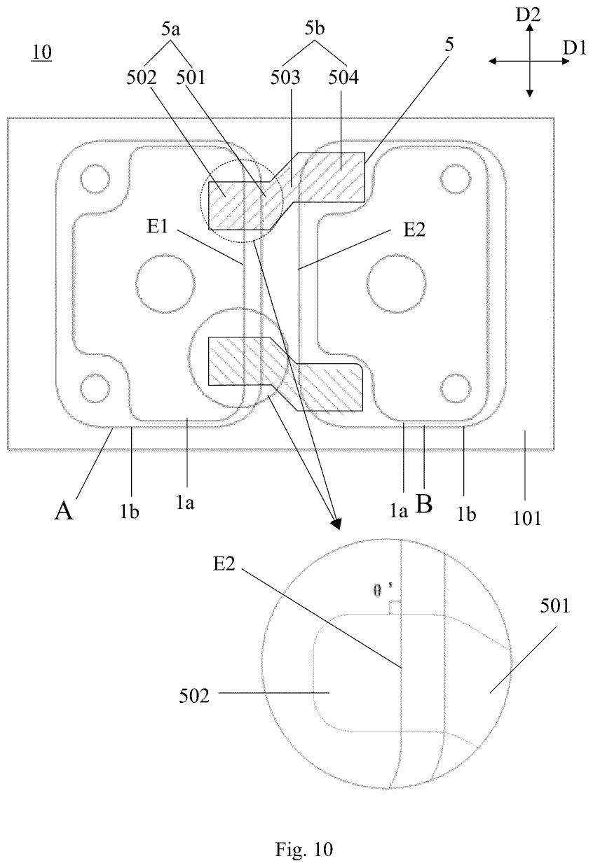

In this regard, FIG. 10 is a planar schematic diagram of a structure of still another light-emitting device provided by an embodiment of the present disclosure. Referring to FIG. 10, for example, the first sub-light-emitting unit A and the second sub-light-emitting unit B are arranged in the first direction D1, a single bridge electrode 5 extends along the first direction D1 as a whole. For the single bridge electrode 5, the bridge electrode 5 includes a first extension part 5a. An orthographic projection of the first extension part 5a on the horizontal plane is overlapped with an orthographic projection of the first sub-light-emitting unit A on the horizontal plane, for example, the orthographic projection of the first extension part 5a on the horizontal plane is overlapped with the orthographic projection of the first semiconductor layer 1a of the first sub-light-emitting unit A. The first extension part 5a includes a first part 501 and a second part 502 that are connected with each other; the first semiconductor layer 1a of the first sub-light-emitting unit A has a first edge E1 close to the second sub-light-emitting unit B; for example, the first extension part 5a extends across the first edge E1 of the first sub-light-emitting unit A along the first direction D1, to be overlapped with the first semiconductor layer 1a of the first sub-light-emitting unit A; for example, the first edge E1 extends along the second direction D2; an orthographic projection of the first edge E1 on the horizontal plane is a boundary between an orthographic projection of the first part 501 on the horizontal plane and an orthographic projection of the second part 502 on the horizontal plane, the orthographic projection of the first part 501 on the horizontal plane is overlapped with the orthographic projection of the first semiconductor layer 1a of the first sub-light-emitting unit A on the horizontal plane, the orthographic projection of the second part 502 on the horizontal plane is not overlapped with the orthographic projection of the first semiconductor layer 1a of the first sub-light-emitting unit A on the horizontal plane; an extension direction of the second part 502 is substantially perpendicular to the first edge E1. In this way, starting from the position where the second part 502 of the bridge electrode (equivalent to a part of the above-mentioned bridge electrode 051) is overlapped with the first edge E1, along the first direction D1, the second portion 502 has an overlapping area with the first semiconductor layer 1a of the first sub-light-emitting unit A that remains substantially constant, a thickness of the second part 502 is uniform, and there are no gradual islands, it is not easy to produce the above-mentioned tip protrusion during the manufacturing process of the bridge electrode, therefore, the second insulating layer formed above the bridge electrode is not prone to cracking, and the above-mentioned problems of leakage, poor sealing, and uneven thickness of the bridge electrode are avoided.

For example, for a single bridge electrode 5, the bridge electrode 5 includes a second extension part 5b, the second extension part 5b includes a third part 503 and a fourth part 504 that are connected with each other, the second semiconductor layer 1b of the second sub-light-emitting unit B has a second edge E2 close to the first sub-light-emitting unit A. For example, the second extension part 5b extends across the second edge E2 of the second sub-light-emitting unit B along the first direction D1, to be overlapped with the second semiconductor layer 1b of the second sub-light-emitting unit B. An orthographic projection of the second edge E2 on the horizontal plane is a boundary between an orthographic projection of the third part 503 on the horizontal plane and an orthographic projection of the fourth part 504 on the horizontal plane, the orthographic projection of the third part 503 on the horizontal plane is overlapped with the orthographic projection of the second semiconductor layer 1b of the second sub-light-emitting unit B on the horizontal plane, the orthographic projection of the fourth part 504 on the horizontal plane is not overlapped with the orthographic projection of the second semiconductor layer 1b of the second sub-light-emitting unit B on the horizontal plane; and an extension direction of the fourth portion 504 is substantially perpendicular to the second edge E2. Therefore, similarly, starting from a position where the fourth part 504 of the bridge electrode (equivalent to a part of the second end of the bridge electrode similar to the bridge electrode 051) is overlapped with the second edge E2, along the first direction D1, the fourth portion 504 has an overlapping area with the second semiconductor layer 1b of the second sub-light-emitting unit B that remains substantially constant, a thickness of the fourth part 504 is uniform, and there are no gradual islands, it is not easy to produce the above-mentioned tip protrusion during the manufacturing process of the bridge electrode, therefore, the second insulating layer formed above the bridge electrode is not prone to cracking, and the above-mentioned problems of leakage, poor sealing, and uneven thickness of the bridge electrode are avoided.

For example, as shown in FIG. 10, the first extension part 5a of the bridge electrode 5 includes a first interface portion covering the first edge E1, the first interface portion includes the above-mentioned first part 51 and second part 502, the second extension part 5b of the bridging electrode 5 includes a second interface portion covering the second edge E2, the second interface portion includes the above-mentioned third part 503 and fourth part 504; along the first direction D1, a thickness of the first interface part is uniform in the longitudinal direction, and a thickness of the second interface part in the longitudinal direction is uniform, therefore, the performance of the bridge electrode 5 is made more stable, and the signal transmission efficiency on the bridge electrode 5 is improved.

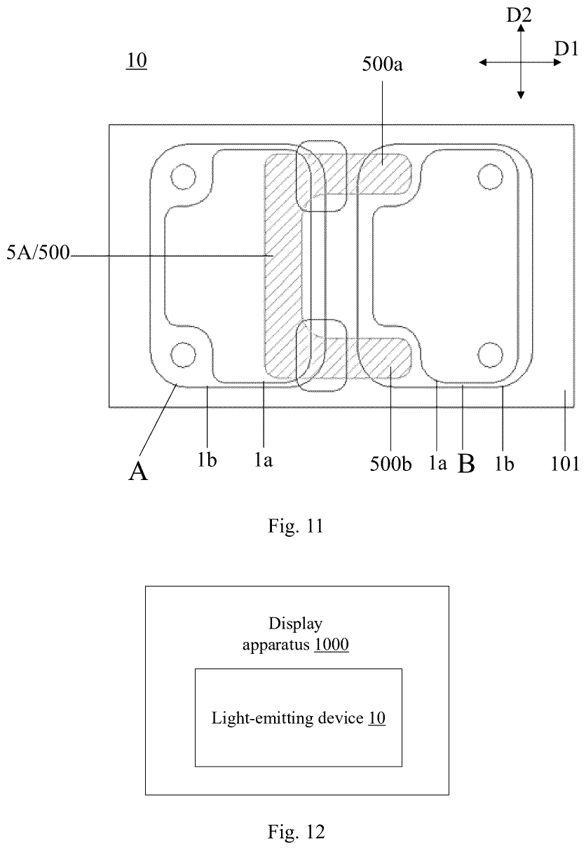

FIG. 11 is a planar schematic diagram of a structure of still another light-emitting device provided by an embodiment of the present disclosure. Referring to FIG. 11, for example, the first sub-light-emitting units A and the second sub-light-emitting units B are arranged in the first direction D1, a length of a first end of the bridge electrode 5 in the second direction D2 is greater than ½ of a length of the first semiconductor layer 1a of the first sub-light-emitting unit A in the second direction D2, and the second direction D2 is perpendicular to the first direction D1. For example, the length of the first end 5A of the bridge electrode 5 in the second direction D2 is substantially the same as the length of the first semiconductor layer 1a of the first sub-light-emitting unit A in the second direction D2, that is, the longer length in the second direction D2, which is beneficial to reducing the resistance of the bridge electrode 5 for signal conduction along the first direction D1.

Referring to FIG. 11, for example, the bridge electrode 5 includes a connection portion 500 and a plurality of branches 500a/500b, a first end of each of the plurality of branches 500a/500b is electrically connected with the first semiconductor layer 1a of the first sub-light-emitting unit A, and the first ends of the plurality of branches 500a/500b are all electrically connected with the connection part 500, the connection part 500 is in direct contact with at least one of the current spreading layer 2 of the first sub-light-emitting unit A and the first semiconductor layer 1a of the first sub-light-emitting unit A, for example, through a via hole contact or, they are directly attached to each other by the entire surfaces facing each other. A length of the connection portion 500 in the second direction D2 is greater than ½ of the length of the first semiconductor layer 1a of the first sub-light-emitting unit A in the second direction D2, for example, the length of the connection portion 500 in the second direction D2 and the length of the first semiconductor layer 1a of the first sub-light-emitting unit A in the second direction D2 are substantially the same. In this way, the plurality of branches are connected in parallel to further reduce the resistance of the bridge electrode 5 for signal conduction along the first direction D1, at the same time, the length of the connection portion 500 is longer, which is beneficial to reducing the resistance of the bridge electrode 5 for signal transmission along the first direction D1.

Referring to FIG. 11, for example, the connection portion 500 is located in an edge region of the first sub-light-emitting unit A close to the second sub-light-emitting unit B and is in a strip shape extending along the second direction D2, so that the signal transmission path of the bridge electrode is shortened, and the resistance of the bridge electrode is reduced.

At least one embodiment of the present disclosure also provides a display apparatus, FIG. 12 is a schematic diagram of an electronic equipment provided by an embodiment of the present disclosure. Referring to FIG. 12, in a display apparatus 1000 provided by an embodiment of the present disclosure, the display apparatus 1000 includes any one of the light-emitting devices 10 provided by the embodiments of the present disclosure. For example, the display apparatus 1000 includes a light emitting array, the light-emitting array includes a plurality of light-emitting devices 10 arranged in an array. For example, the display apparatus can be: a monitor, a display panel, a TV, an electronic paper, a mobile phone, a tablet computer, a laptop computer, a digital photo frame, a navigator, or any other product or component with a display function. Of course, the display apparatus is not limited to the types listed above.

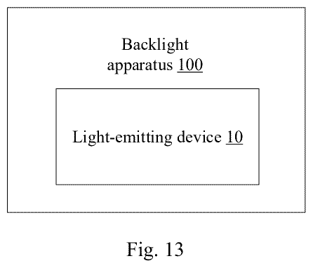

At least one embodiment of the present disclosure further provides a backlight apparatus, FIG. 13 is a schematic block diagram of a backlight apparatus provided by an embodiment of the present disclosure. Referring to FIG. 13, the backlight apparatus 100 provided by the embodiment of the present disclosure includes any one of the light-emitting devices 10 provided by the embodiments of the present disclosure. The backlight apparatus 100 can be used as a backlight source for any electronic equipment that requires backlight. For example, the backlight apparatus 100 includes a light emitting array, and the light-emitting array includes a plurality of light-emitting devices 10 arranged in an array.

At least one embodiment of the present disclosure further provides an electronic equipment, and the electronic equipment provided by the embodiment of the present disclosure includes any one of the backlight apparatuses 100 provided by the embodiments of the present disclosure.

For example, the electronic equipment may be a display apparatus, and the backlight apparatus 100 serves as a backlight source of the display apparatus; the display apparatus is, for example, a liquid crystal display apparatus, or any other display apparatus that requires a backlight. For example, the display apparatus can be: a monitor, a display panel, a TV, an electronic paper, a mobile phone, a tablet computer, a laptop computer, a digital photo frame, a navigator, or any other product or component with a display function. Of course, the specific type of the display apparatus is not limited to the types listed above.

For example, the electronic equipment may be a lighting device, such as a lamp, and the backlight apparatus 100 serves as a backlight source of the lighting device and provides a light source for the lighting device.

What have been described above are only specific implementations of the present disclosure, the protection scope of the present disclosure is not limited thereto, and the protection scope of the present disclosure should be determined by the protection scope of the claims.

1. A light-emitting device, comprising a sub-light-emitting unit, wherein the sub-light-emitting unit comprises:
a first semiconductor layer;
a second semiconductor layer, stacked with the first semiconductor layer and having a material different from a material of the first semiconductor layer;
a light-emitting layer, located between the first semiconductor layer and the second semiconductor layer;
a current spreading layer, located on a side of the first semiconductor layer away from the second semiconductor layer; and
an insulating layer, located between the current spreading layer and the first semiconductor layer, wherein the current spreading layer and the second semiconductor layer are electrically connected with the first semiconductor layer through a via hole penetrating the insulating layer.

2. The light-emitting device according to claim 1, wherein a direction along which the first semiconductor layer and the second semiconductor layer are stacked is a longitudinal direction, a plane perpendicular to the longitudinal direction is a horizontal plane;
an area of an orthographic projection of the current spreading layer on the horizontal plane is smaller than an area of an orthographic projection of the first semiconductor layer on the horizontal plane, and is located within an orthographic projection of the first semiconductor layer on the horizontal plane.

3. The light-emitting device according to claim 2, wherein the area of the orthographic projection of the current spreading layer on the horizontal plane is less than ½ of the area of the orthographic projection of the first semiconductor layer on the horizontal plane; and in at least one direction in the horizontal plane, a size of the current spreading layer does not exceed 2 times of a size of the via hole.

4. The light-emitting device according to claim 1, wherein a direction along which the first semiconductor layer and the second semiconductor layer are stacked is a longitudinal direction, and a plane perpendicular to the longitudinal direction is a horizontal plane; and
an orthographic projection of the current spreading layer on the horizontal plane substantially coincides with an orthographic projection of the first semiconductor layer on the horizontal plane.

5. The light-emitting device according to claim 1, wherein the light-emitting device comprises a plurality of the sub-light-emitting units, the plurality of sub-light-emitting units comprise a first sub-light-emitting unit and a second sub-light-emitting unit;
the light-emitting device further comprises a bridge electrode, the bridge electrode electrically connects a first semiconductor layer of the first sub-light-emitting unit with a second semiconductor layer of the second sub-light-emitting unit; and
a first end of the bridge electrode is electrically connected with the first semiconductor layer of the first sub-light-emitting unit.

6. The light-emitting device according to claim 5, wherein the first end of the bridge electrode comprises an annular part, and the annular part at least partially surrounds a via hole of the first sub-light-emitting unit.

7. The light-emitting device according to claim 6, wherein the first end of the bridge electrode is in direct contact with at least one of the current spreading layer of the first sub-light-emitting unit and the first semiconductor layer of the first sub-light-emitting unit.

8. The light-emitting device according to claim 6, wherein, in a case where a direction along which the first semiconductor layer and the second semiconductor layer are stacked is a longitudinal direction, and a plane perpendicular to the longitudinal direction is a horizontal plane, an area of an orthographic projection of the current spreading layer on the horizontal plane is smaller than an area of an orthographic projection of the first semiconductor layer on the horizontal plane, and is located within the orthographic projection of the first semiconductor layer on the horizontal plane,
the annular part at least partially surrounds the current spreading layer of the first sub-light-emitting unit, and
the annular part is in direct contact with the first semiconductor layer of the first sub-light-emitting unit, or the annular part is in direct contact with the insulating layer.

9. The light-emitting device according to claim 8, wherein a surface of the annular part facing the first semiconductor layer of the first sub-light-emitting unit is in direct contact with a surface of the first semiconductor layer of the first sub-light-emitting unit facing the annular part.

10. The light-emitting device according to claim 9, wherein, in a case where the direction along which the first semiconductor layer and the second semiconductor layer are stacked is the longitudinal direction, the plane perpendicular to the longitudinal direction is the horizontal plane, and the orthographic projection of the current spreading layer on the horizontal plane substantially coincides with the orthographic projection of the first semiconductor layer on the horizontal plane, and
the annular part at least partially surrounds the via hole of the first sub-light-emitting unit, and is in contact with the current spreading layer.

11. The light-emitting device according to claim 10, wherein the surface of the annular part facing the current spreading layer of the first sub-light-emitting unit is in direct contact with the surface of the current spreading layer of the first sub-light-emitting unit facing the annular part.

12. (canceled)

13. The light-emitting device according to claim 6, wherein a line width in a radial direction of the annular part is greater than a distance from an inner ring of the annular part close to the via hole to a center of the via hole, and the radial direction comprises a direction from an annular center of the annular part to a circumference of the annular part.

14. The light-emitting device according to claim 5, wherein the light-emitting device comprises a plurality of the bridge electrodes, the first end of each of the plurality of the bridge electrodes is electrically connected with the first semiconductor layer of the first sub-light-emitting unit, and the first end of at least one of the bridge electrodes comprises the annular part.

15. The light-emitting device according to claim 14, wherein the plurality of bridge electrodes comprise a first bridge electrode and a second bridge electrode, the first sub-light-emitting unit comprises a plurality of via holes, and the plurality of via holes comprise a first sub-via hole and a second sub-via hole; and
both of a first end of the first bridge electrode and a first end of the second bridge electrode comprise the annular part, the annular part of the first end of the first bridge electrode at least partially surrounds the first sub-via hole, and the annular part of the first end of the second bridge electrode at least partially surrounds the second sub-via hole,
in a case where the annular part at least partially surrounds the current spreading layer of the first sub-light-emitting unit,
the first sub-light-emitting unit comprises a plurality of current spreading layers, the plurality of currently spreading layers comprise a first spreading layer and a second spreading layer that are electrically connected with the first semiconductor layer of the first sub-light-emitting unit through the first sub-via hole and the second sub-via hole, respectively, the annular part of the first end of the first bridge electrode at least partially surrounds the first spreading layer, and the annular part of the first end of the second bridge electrode at least partially surrounds the second spreading layer.

16. (canceled)

17. The light-emitting device according to claim 5, wherein the first sub-light-emitting unit and the second sub-light-emitting unit are arranged along a first direction, the bridge electrode as a whole extends along the first direction; a direction along which the first semiconductor layer and the second semiconductor layer are stacked is a longitudinal direction, and a plane perpendicular to the longitudinal direction is a horizontal plane;
for the bridge electrode, the bridge electrode comprises a first extension part, an orthographic projection of the first extension part on the horizontal plane is overlapped with an orthographic projection of the first sub-light-emitting unit on the horizontal plane, the first extension part comprises a first part and a second part connected with each other; the first semiconductor layer of the first sub-light-emitting unit has a first edge close to the second sub-light-emitting unit, an orthographic projection of the first edge on the horizontal plane is a boundary of an orthographic projection of the first part on the horizontal plane and an orthographic projection of the second part on the horizontal plane, the orthographic projection of the first part on the horizontal plane is overlapped with the orthographic projection of the first semiconductor layer of the first sub-light-emitting unit on the horizontal plane, the orthographic projection of the second part on the horizontal plane is not overlapped with the orthographic projection of the first semiconductor layer of the first sub-light-emitting unit on the horizontal plane; and
an extension direction of the first part is substantially perpendicular to the first edge.

18. The light-emitting device according to claim 17, wherein
for the bridge electrode, the bridge electrode comprises a second extension part, the second extension part comprises a third part and a fourth part connected to each other, the second semiconductor layer of the second sub-light-emitting unit has a second edge close to the first sub-light-emitting unit, an orthographic projection of the second edge on the horizontal plane is a boundary of an orthographic projection of the third part on the horizontal plane and an orthographic projection of the fourth part on the horizontal plane, the orthographic projection of the third part on the horizontal plane is overlapped with the orthographic projection of the second semiconductor layer of the second sub-light-emitting unit on the horizontal plane, the orthographic projection of the fourth part on the horizontal plane is not overlapped with the orthographic projection of the second semiconductor layer of the second sub-light-emitting unit on the horizontal plane; and
an extension direction of the third part is substantially perpendicular to the second edge.

19. The light-emitting device according to claim 18, wherein the first extension part of the bridge electrode comprises a first interface part covering the first edge, a second extension part of the bridge electrode comprises a second interface part covering the second edge;
along the first direction, a thickness of the first interface part in the longitudinal direction is uniform, and a thickness of the second interface part in the longitudinal direction is uniform.

20. The light-emitting device according to claim 5, wherein the first sub-light-emitting unit and the second sub-light-emitting unit are arranged in the first direction,
a length of the first end of the bridge electrode in a second direction is greater than ½ of a length of the first semiconductor layer of the first sub-light-emitting unit in the second direction, and the second direction is perpendicular to the first direction.

21. The light-emitting device according to claim 20, wherein the bridge electrode comprises a connection part and a plurality of branches, a first end of each of the plurality of branches is electrically connected with the first semiconductor layer of the first sub-light-emitting unit, and the first end of each of the plurality of branches are electrically connected with the connection part, the connection part is in direct contact with at least one of the current spreading layer of the first sub-light-emitting unit and the first semiconductor layer of the first sub-light-emitting unit; and
a length of the connection part in the second direction is greater than ½ of a length of the first semiconductor layer of the first sub-light-emitting unit in the second direction.

22. (canceled)

23. (canceled)

24. The light-emitting device according to claim 1, wherein the light-emitting device is a Mini Light Emitting Diode or a Micro Light Emitting Diode;
a material of the current spreading layer is a transparent conductive material;
the material of the first semiconductor is a P-type semiconductor material, and the material of the second semiconductor is an N-type semiconductor material, or the material of the first semiconductor is an N-type semiconductor material, and the material of the second semiconductor is a P-type semiconductor material.

25. (canceled)

26. (canceled)
